(19) United States
(12) Patent Application Publication
(10) Pub. No.: US 2026/0319991 A1
(43) Pub. Date: Oct. 15, 2026

(54) SYSTEM AND METHOD FOR DETECTING HARDWARE VERSION

(71) Applicant: Alpha Networks Inc., Hsinchu (TW)

(72) Inventors: Shih-Chieh SU, Hsinchu (TW); Yi-Peng CHENG, Hsinchu (TW); Chia Ying YANG, Hsinchu (TW); Ming-Feng LIN, Hsinchu (TW)

(73) Assignee: Alpha Networks Inc., Hsinchu (TW)

(21) Appl. No.: 19/378,103

(22) Filed: Nov. 3, 2025

(30) Foreign Application Priority Data
Apr. 15, 2025 (TW) 114114207

(51) Int. Cl. G06F 13/40; G11C 7/06; G11C 7/10

(52) U.S. Cl. CPC G06F 13/4072; G11C 7/06; G11C 7/1051

(57) ABSTRACT

A system for detecting hardware version includes a detection circuit and a timing circuit. The detection circuit includes a counter to generate a current count value, an input/output (IO) pin, an IO circuit, and a controller. The controller controls the IO circuit to operate in an output mode to pull the voltage at the IO pin to a first voltage level, sets the counter to a predetermined minimum count value, controls the IO circuit to operate in an input mode to allow the timing circuit to pull the voltage at the IO pin to a second voltage level, controls the counter to start counting, and, in response to receipt of an indication signal from the IO circuit, controls the counter to stop counting, and obtains a current hardware version data set based on the current count value after the counter has stopped counting.

### CROSS-REFERENCE TO RELATED APPLICATION

This application claims priority to Taiwanese Invention Patent Application No. 114114207, filed on Apr. 15, 2025, the entire disclosure of which is incorporated by reference herein.

### FIELD

The disclosure relates to a system and a method for detecting hardware version.

### BACKGROUND

In a hardware development process, testing of hardware is often required when there are hardware specification changes and software updates. Therefore, hardware versions are usually marked to facilitate differentiation between different hardware versions, thereby making it convenient for version control and enabling development personnel to easily track the hardware versions and switch hardware support for new software functions. Conventional hardware version identification methods include: using resistors to pull general-purpose input/output (GPIO) pins to high or low voltage levels for encoding and identification; or using a voltage divider circuit for identification, which uses an analog-to-digital converter (ADC) on the hardware to read a divided voltage value of the voltage divider circuit to detect the hardware version; or using additional storage devices to store relevant hardware version information, and then reading the storage devices to ascertain the hardware version when needed.

However, with the aforementioned conventional hardware version identification methods, for example: using resistors to pull the GPIO pins to high or low voltage levels requires occupying multiple GPIO pins; using the voltage divider circuit and relying on the ADC on the hardware require the hardware to support this function; and using the additional storage devices may increase development costs.

### SUMMARY

Therefore, an object of the disclosure is to provide a system and a method for detecting hardware version that can alleviate at least one of the drawbacks of the prior art.

According to an aspect of the disclosure, the system for detecting hardware version includes a detection circuit and a timing circuit. The detection circuit includes a counter configured to generate a current count value, an input/output (IO) pin, an IO circuit electrically connected to the IO pin, and a controller electrically connected to the counter and the IO circuit. The IO circuit is configured to pull a voltage at the IO pin to a first voltage level when operating in an output mode, and to generate an indication signal based on the voltage at the IO pin when operating in an input mode. The indication signal indicates whether the voltage at the IO pin is between a reference voltage level and a second voltage level. The second voltage level is different from the first voltage level. The reference voltage level is between the first voltage level and the second voltage level. The controller is configured to receive the current count value from the counter, and to receive the indication signal from the IO circuit. The timing circuit is electrically connected to the IO pin, and is configured to pull the voltage at the IO pin to the second voltage level in response to the IO circuit operating in the input mode. The controller is further configured to control the IO circuit to operate in the output mode to pull the voltage at the IO pin to the first voltage level, and to set the current count value of the counter to a predetermined minimum count value. The controller is further configured to control the IO circuit to operate in the input mode, to control the counter to start counting from the current count value thus set, and to, in response to the indication signal indicating that the voltage at the IO pin is between the reference voltage level and the second voltage level, control the counter to stop counting, and obtain a current hardware version data set based on the current count value after the counter has stopped counting.

According to another aspect of the disclosure, the method for detecting hardware version is to be implemented by a detection circuit that includes an input/output (IO) pin adapted to be electrically connected to a timing circuit. The method includes steps of: operating in an output mode to pull a voltage at the IO pin to a first voltage level; setting a current count value to a predetermined minimum count value; operating in an input mode to allow the timing circuit to pull the voltage at the IO pin to a second voltage level that is different from the first voltage level in response to the detection circuit operating in the input mode, and to start counting to increase the current count value; and obtaining a current hardware version data set based on the current count value.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a block diagram illustrating a system for detecting hardware version according to an embodiment of the disclosure.

FIG. 2 is a flowchart illustrating a first embodiment of a method for detecting hardware version according to the disclosure.

FIG. 3 is a flowchart illustrating a second embodiment of the method for detecting hardware version according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

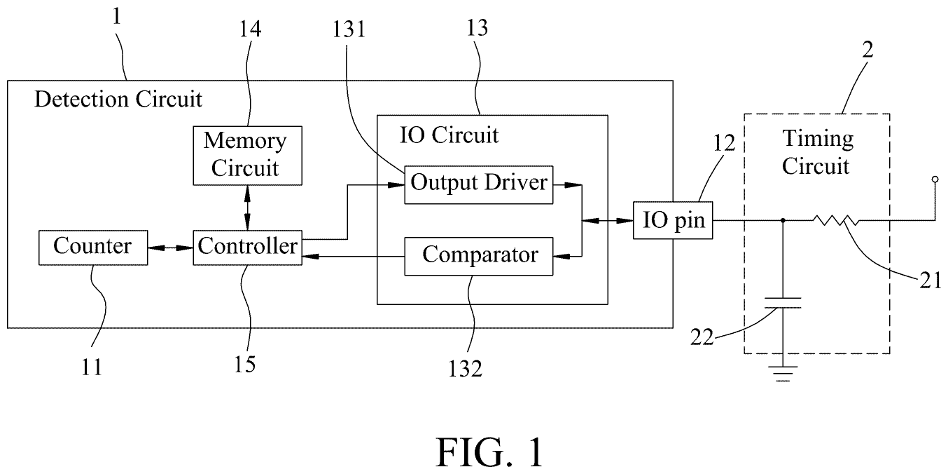

Referring to FIG. 1, a system for detecting hardware version according to an embodiment of the disclosure includes a detection circuit 1, and a timing circuit 2.

The detection circuit 1 includes a counter 11, an input/output (IO) pin 12, an IO circuit 13, a memory circuit 14, and a controller 15.

The counter 11 is configured to generate a current count value based on a reference clock signal. In accordance with some embodiments, the reference clock signal may be received from the controller 15 or derived from an operating frequency of an integrated circuit on which the counter 11 is disposed, but the disclosure is not limited to such.

The detection circuit 1 is configured to transmit and receive electric signals in analog or digital form via the IO pin 12. In one embodiment, the IO pin 12 may be exemplified as a general-purpose input/output (GPIO) pin, but the disclosure is not limited in this respect.

The IO circuit 13 is electrically connected to the IO pin 12, and is configured to pull a voltage at the IO pin 12 to a first voltage level when operating in an output mode, and to generate an indication signal based on the voltage at the IO pin 12 when operating in an input mode. The indication signal indicates whether the voltage at the IO pin 12 is between a reference voltage level and a second voltage level, where the second voltage level is different from the first voltage level, and the reference voltage level is between the first voltage level and the second voltage level. In one embodiment, the first voltage level is one of a predetermined high voltage level and a predetermined low voltage level, and the second voltage level is the other one of the predetermined high voltage level and the predetermined low voltage level. That is to say, in such an embodiment, the reference voltage level is between the predetermined high voltage level and the predetermined low voltage level. In one embodiment, a difference between the reference voltage level and the second voltage level is less than a difference between the reference voltage level and the first voltage level. In this embodiment, the first voltage level is the predetermined low voltage level and the second voltage level is the predetermined high voltage level, where the predetermined low voltage level is 0 volts (i.e., the first voltage level is 0 volts), the predetermined high voltage level is 3.3 volts (i.e., the second voltage level is 3.3 volts), and the reference voltage level is 2.25 volts. That is to say, in this embodiment, the indication signal indicates whether the voltage at the IO pin 12 is between 2.25 volts (i.e., the reference voltage level) and 3.3 volts (i.e., the second voltage level). In other embodiments, the first voltage level may be the predetermined high voltage level and the second voltage level may be the predetermined low voltage level, where the predetermined low voltage level may be 0 volts, and the predetermined high voltage level may be 3.3 volts. In such embodiments, the first voltage level is 3.3 volts, the second voltage level is 0 volts, and the reference voltage level may be 0.8 volts. That is to say, in such embodiments, the indication signal indicates whether the voltage at the IO pin 12 is between 0.8 volts (i.e., the reference voltage level) and 0 volts (i.e., the second voltage level), but the disclosure is not limited in this respect. Specifically, the reference voltage level acts as a threshold voltage level to determine whether the voltage at the IO pin 12 is, in this embodiment, within 3.3 V, greater than or equal to 2.25 V, or in the other embodiments, less than or equal to 0.8 V. In one embodiment, the reference voltage may be predefined by a user, but is not limited to such.

In this embodiment, the IO circuit 13 includes an output driver 131 and a comparator 132. The output driver 131 is electrically connected to the IO pin 12, and is controllable by the controller 15 to selectively pull (i.e., to pull or not to pull) the voltage at the IO pin 12 to the first voltage level. The comparator 132 is electrically connected to the IO pin 12, and is configured to compare the voltage at the IO pin 12 with the reference voltage level in order to generate the indication signal. For example, the output driver 131 may be exemplified by implementations using complementary metal-oxide-semiconductor (MOS) transistors, or by circuits employing resistive pull-up or pull-down elements to pull the voltage at the IO pin 12 to the first voltage level, but the output driver 131 is not limited in this respect.

The memory circuit 14 stores a plurality of hardware version data sets. In this embodiment, the hardware version data sets include a default version data set that is applicable for multiple types of hardware, and a plurality of non-default version data sets each corresponding to one of the multiple types of hardware. The default version data set corresponds to a predetermined minimum count value and a predetermined maximum count value greater than the predetermined minimum count value. The non-default version data sets correspond respectively to a plurality of reference count values that are in between the predetermined minimum count value and the predetermined maximum count value. In this embodiment, the predetermined minimum count value is 0, and the predetermined maximum count value is 1000, but the disclosure is not limited in this respect.

The controller 15 is electrically connected to the counter 11, the output driver 131, the comparator 132, and the memory circuit 14. The controller 15 is configured to receive the current count value from the counter 11, and to receive the indication signal from the comparator 132. The controller 15 is further configured to obtain one of the hardware version data sets that corresponds to the detection circuit 1 from the memory circuit 14 as a current hardware version data set based on the current count value and the reference count values. The controller 15 may be exemplified as a central processing unit (CPU), a microcontroller (MC), a field programmable gate array (FPGA), or a complex programmable logic device (CPLD), but the controller 15 is not limited to such. The memory circuit 14 may be exemplified as a read-only memory (ROM), a programmable read-only memory (PROM), a flash memory, or a combination of the flash memory with a firmware, but the memory circuit 14 is not limited to such.

In another embodiment, the memory circuit 14 may store the hardware version data sets that correspond respectively to a plurality of reference count value ranges. In such an embodiment, the controller 15 is further configured to determine which one of the reference count value ranges covers the current count value, and obtain one of the hardware version data sets that corresponds to said one of the reference count value ranges thus determined from the memory circuit 14 as the current hardware version data set. For example, when the current count value is 115, the controller 15 may select one of the hardware version data sets that corresponds to one of the reference count value ranges, which is from 100 to 120, as the current hardware version data set. When the current count value is equal to the predetermined minimum count value (i.e., 0), the controller 15 selects one of the hardware version data sets that corresponds to the reference count value range that goes from 0 to 50 as the current hardware version data set; when the current count value is the predetermined maximum count value (i.e., 1000), the controller 15 selects one of the hardware version data sets that corresponds to the reference count value range that goes from 950 to 1000 as the current hardware version data set, but the disclosure is not limited in this respect.

In yet another embodiment, the memory circuit 14 may store the hardware version data sets that correspond respectively to a plurality of reference count value sets. The reference count value sets include the predetermined minimum count value that corresponds to the default version data set, and a plurality of reference value ranges that correspond respectively to the non-default version data sets. Each of the reference value ranges has a lower boundary that is greater than the predetermined minimum count value. For example, in one of the reference value ranges that has a value range of 1 to 10, the lower boundary is the smallest value in the value range, which in this case is 1. In the yet another embodiment, the controller 15 is further configured to determine which one of the reference count value sets corresponds to the current count value, and will obtain one of the hardware version data sets that corresponds to said one of the reference count value sets thus determined from the memory circuit 14 as the current hardware version data set. For example, in such an embodiment, the predetermined minimum count value may be 0, and the reference value ranges may include a range from 1 to 99, and a range of values greater than or equal to 100. In a case where the current count value is 0, the controller 15 obtains one of the hardware version data sets that corresponds to the predetermined minimum count value (in this case is the default version data set) as the current hardware version data set; in another case where the current count value is greater than 0, the controller 15 obtains one of the hardware version data sets that corresponds to one of the reference value ranges within which the current count value is included (e.g., the current count value of 20 is included in the reference value range from 1 to 99) as the current hardware version data set, which is one of the non-default version data sets in this case, but the disclosure is not limited in this respect.

The timing circuit 2 is electrically connected to the IO pin 12, and is configured to pull the voltage at the IO pin 12 to the second voltage level in response to the IO circuit 13 operating in the input mode. Specifically, when the IO circuit 13 is operating in the input mode, the controller 15 does not control the output driver 131 to pull the voltage at the IO pin 12 to the first voltage level (i.e., 0 volts in this embodiment). At this time, the timing circuit 2 pulls the voltage at the IO pin 12 to the second voltage level (i.e., 3.3 volts in this embodiment).

In this embodiment, the timing circuit 2 includes a resistor 21 and a capacitor 22. The resistor 21 has a first terminal for receiving a first preset voltage at the second voltage level, and a second terminal electrically connected to the IO pin 12. The capacitor 22 has a first terminal electrically connected to the IO pin 12, and a second terminal for receiving a second preset voltage. In this embodiment, the first terminal of the resistor 21 is electrically connected to a power source (not shown) for receiving the first preset voltage at the second voltage level (i.e., the predetermined high voltage level of 3.3 volts in this embodiment), and the second terminal of the capacitor 22 is electrically connected to a ground for receiving the second preset voltage at the predetermined low voltage level (i.e., 0 volts in this embodiment), but the second preset voltage is not limited to such. In other embodiments where the second voltage level is the predetermined low voltage level, the first terminal of the resistor 21 is electrically connected to the ground for receiving the first preset voltage at 0 volts. It should be noted that a resistance value of the resistor 21 and a capacitance value of the capacitor 22 are predetermined by the user, where different combinations of the resistance value of the resistor 21 and the capacitance value of the capacitor 22 correspond respectively to the hardware version data sets.

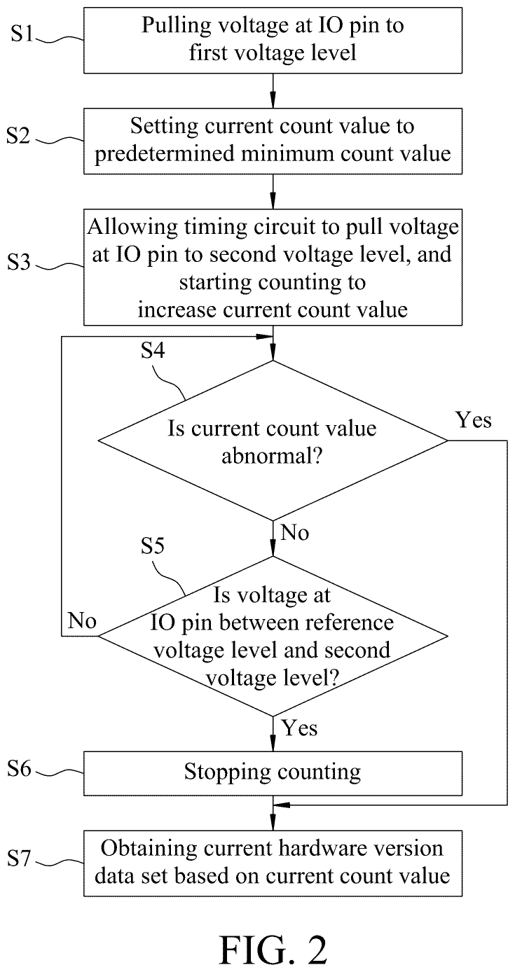

Referring to FIGS. 1 and 2, a method for detecting hardware version according to a first embodiment of the disclosure is implemented by the detection circuit 1 of FIG. 1. In the first embodiment, the method includes steps S1 to S7.

In step S1, the controller 15 controls the output driver 131 to operate in the output mode to pull the voltage at the IO pin 12 to the first voltage level. In this embodiment, the controller 15 controls the output driver 131 to operate in the output mode for a first predetermined period of time in order to let the voltage at the IO pin 12 to be pulled to the first voltage level (i.e., a voltage across the capacitor 22 will be pulled to 0 volts). The first predetermined period of time may be calculated based on the resistance value of the resistor 21 and the capacitance value of the capacitor 22.

In step S2, the controller 15 sets the current count value of the counter 11 to the predetermined minimum count value (i.e., 0 in this embodiment).

In step S3, the controller 15 controls the output driver 131 to operate in the input mode to allow the timing circuit 2 to pull the voltage at the IO pin 12 to the second voltage level, and controls the counter 11 to start counting to increase the current count value. It should be noted that the current count value continuously increases during the time the timing circuit 2 pulls the voltage at the IO pin 12 to the second voltage level. Accordingly, the longer time the timing circuit 2 takes to pull the voltage at the IO pin 12 to the second voltage level, the higher the current count value.

In step S4, the controller 15 determines whether the current count value is abnormal. If the determination in step S4 is affirmative, the flow goes to step S7; the flow goes to step S5 if the determination in step S4 is otherwise.

In this embodiment, the current count value is determined to be abnormal when current count value fulfils a first predetermined condition, that is, if the current count value is equal to the predetermined minimum count value or the predetermined maximum count value. That is to say, the controller 15 determines that the current count value is abnormal when the current count value is equal to the predetermined minimum count value or the predetermined maximum count value.

In step S5, the controller 15 determines whether the voltage at the IO pin 12 is between the reference voltage level and the second voltage level based on the indication signal received from the comparator 132. If the determination in step S5 is affirmative, the flow goes to step S6; the flow goes to step S4 when the determination in step S5 is otherwise.

In step S6, the controller 15 controls the counter 11 to stop counting in order to stop the increase of the current count value. At this time, the current count value after the counter 11 has stopped counting corresponds to the time duration taken for the timing circuit 2 to pull the voltage at the IO pin 12 from the first voltage level to the reference voltage level, which is positively related to a product of the resistance value of the resistor 21 and the capacitance value of the capacitor 22.

In step S7, the controller 15 obtains the current hardware version data set based on the current count value. Specifically, in this embodiment, the controller 15 receives the current count value from the counter 11, selects one of the hardware version data sets from the memory circuit 14 as the current hardware version data set, where the selected one of the hardware version data sets corresponds to one of the reference count values, the predetermined maximum count value and the predetermined minimum count value that is closest to the current count value.

It should be noted that, when the determination in step S4 is affirmative and the flow goes to step S7, the controller 15 selects the default version data set as the current hardware version data set in order to ensure that the detection circuit 1 obtains a workable hardware version data set (i.e., the default version data set) even when the counter 11 may be constantly producing the predetermined minimum count value or the predetermined maximum count value, which indicates that the counter 11 may be faulty. When the flow goes from step S6 to step S7, the controller 15 selects one of the non-default version data sets as the current hardware version data set.

In one variation of the first embodiment, the IO circuit 13 may further include a pull-up resistor (not shown) electrically connected to the IO pin 12. In such a variation, the controller 15 disconnects the connection between the pull-up resistor and the IO pin 12 in step S2, so as to prevent disruption of the timing circuit 2 pulling the voltage at the IO pin 12 to the second voltage level.

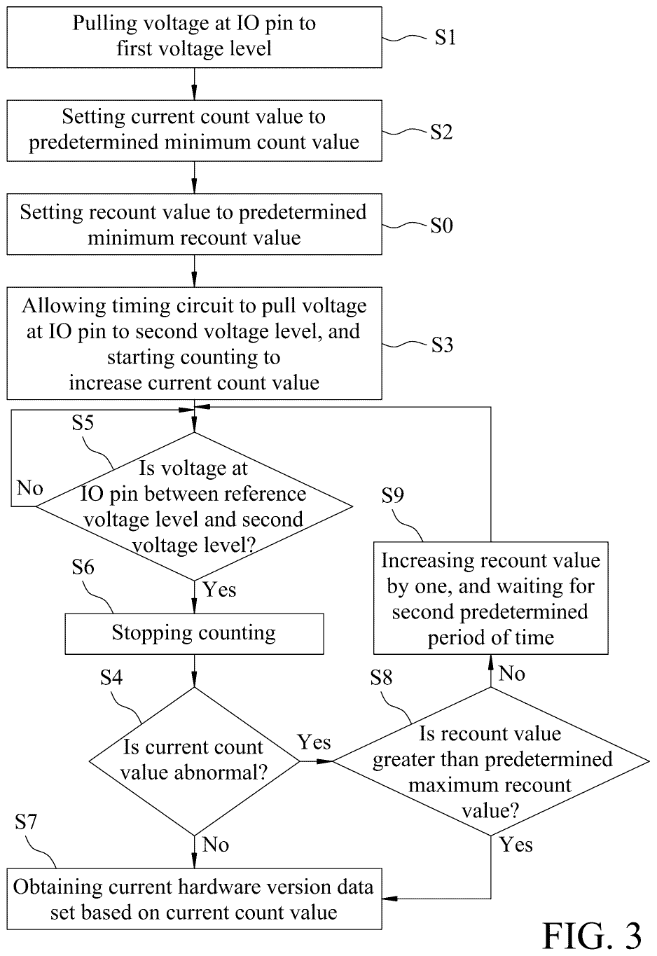

Referring to FIGS. 1 and 3, the method for detecting hardware version according to a second embodiment of the disclosure is implemented by the detection circuit 1 of FIG. 1. In the second embodiment, the method includes steps S0 to S9.

The second embodiment is similar to the first embodiment and differs in the following. In the second embodiment, the method further includes steps S0, S8 and S9. Step S0 is to be executed in between steps S2 and S3. In addition, step S4 is to be executed in between steps S6 and S7, and step S5 is to be executed after step S3.

In step S5 of the second embodiment, when the controller 15 determines that the voltage at the IO pin 12 is between the reference voltage level and the second voltage level, the flow goes to step S6. The flow goes back to step S5 where step S5 is repeated when the determination in step S5 is otherwise.

In step S0, the controller 15 sets a recount value to a predetermined minimum recount value. The recount value corresponds to a number of times the controller 15 executes step S4. For example, the predetermined minimum recount value may be 0, but is not limited to such.

In step S4, the controller 15 determines whether the current count value of the counter 11 is abnormal. If the determination in step S4 is affirmative, the flow goes to step S8; the flow goes to step S7 when the determination in step S4 is otherwise. In the second embodiment, the current count value is determined to be abnormal when the current count value fulfils a second predetermined condition that is, the current count value is equal to the predetermined minimum count value.

In step S8, the controller 15 determines whether the recount value is greater than a predetermined maximum recount value. The predetermined maximum recount value is greater than the predetermined minimum recount value. In one embodiment, the predetermined maximum recount value may be determined by the user, but is not limited to such. For example, the predetermined maximum recount value may be 2. When the determination in step S8 is affirmative, the flow goes to step S7; when the determination in step S8 is otherwise, the flow goes to step S9.

In step S9, the controller 15 increases the recount value by one, waits for a second predetermined period of time, and after the second predetermined period of time has passed, repeats step S5. For example, the second predetermined period of time may be 1 second, but is not limited to such. The second predetermined period of time may be determined by the user. The second predetermined period of time is used to provide a time gap before the flow goes to step S5 and subsequently to steps S6 and S4. By virtue of this arrangement, the controller 15 is able to determine whether the current count value is indeed abnormal before the flow goes to step S7.

It should be noted that, when the determination in step S8 is affirmative and the flow goes to step S7, the controller 15 selects the default version data set as the current hardware version data set in order to ensure that the detection circuit 1 obtains a workable hardware version data set (e.g., the default version data set) even when the counter 11 may be constantly producing the predetermined minimum count value. When the flow goes from step S4 to step S7 (i.e., the determination in step S4 is negative), the controller 15 obtains one of the non-default version data sets as the current hardware version data set.

In summary, when a device equipped with the detection circuit 1 is powered on or is reset to the factory setting, the detection circuit 1 may execute the method for detecting hardware version of this disclosure. The timing circuit 2 is electrically connected to the IO pin 12. The controller 15 first controls the IO circuit 13 to operate in the output mode where the output driver 131 pulls the voltage at the IO pin 12 to the first voltage level, and then the controller 15 controls the IO circuit 13 to operate in the input mode, so that the timing circuit 2 pulls the voltage at the IO pin 12 to the second voltage level. By virtue of the controller 15 obtaining the indication signal from the comparator 132 to determine whether the voltage at the IO pin 12 is between the reference voltage level and the second voltage level, obtaining the current count value from the counter 11 that indicates the time duration taken for the voltage at the IO pin 12 to be pulled from the first voltage level to the reference voltage level, and obtaining the current hardware version data set based on the current count value thus obtained, the system of this disclosure is able to detect the hardware version through the IO pin 12, thereby avoiding the need for multiple IO pins, analog-to-digital converters, or additional storage devices, and contributing to cost savings.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A system for detecting hardware version, comprising:
a detection circuit including
a counter configured to generate a current count value,
an input/output (IO) pin,
an IO circuit electrically connected to said IO pin, and configured to pull a voltage at said IO pin to a first voltage level when operating in an output mode, and to generate an indication signal based on the voltage at said IO pin when operating in an input mode, the indication signal indicating whether the voltage at said IO pin is between a reference voltage level and a second voltage level, where the second voltage level is different from the first voltage level, and the reference voltage level is between the first voltage level and the second voltage level, and
a controller electrically connected to said counter and said IO circuit, and configured to receive the current count value from said counter, and to receive the indication signal from said IO circuit; and
a timing circuit electrically connected to said IO pin, and configured to pull the voltage at said IO pin to the second voltage level in response to said IO circuit operating in the input mode,
wherein said controller is further configured to control said IO circuit to operate in the output mode to pull the voltage at said IO pin to the first voltage level, and to set the current count value of said counter to a predetermined minimum count value,
wherein said controller is further configured to control said IO circuit to operate in the input mode, to control said counter to start counting from the current count value thus set, and to, in response to the indication signal indicating that the voltage at said IO pin is between the reference voltage level and the second voltage level, control said counter to stop counting, and obtain a current hardware version data set based on the current count value after said counter has stopped counting.

2. The system as claimed in claim 1, wherein said timing circuit includes:
a resistor having a first terminal for receiving a first preset voltage at the second voltage level and a second terminal electrically connected to said IO pin; and
a capacitor having a first terminal electrically connected to said IO pin, and a second terminal for receiving a second preset voltage.

3. The system as claimed in claim 1, wherein said IO circuit includes:
an output driver electrically connected to said IO pin and said controller, and controlled by said controller to selectively pull the voltage at said IO pin to the first voltage level; and
a comparator electrically connected to said IO pin and said controller, and configured to compare the voltage at said IO pin with the reference voltage level in order to generate the indication signal.

4. The system as claimed in claim 1, further comprising:
a memory circuit electrically connected to said controller, and storing a plurality of hardware version data sets, the plurality of hardware version data sets corresponding respectively to a plurality of reference count values,
wherein said controller is configured to obtain one of the plurality of hardware version data sets from said memory circuit as the current hardware version data set based on the current count value and the plurality of reference count values.

5. The system as claimed in claim 1, further comprising:
a memory circuit electrically connected to said controller, and storing a plurality of hardware version data sets, the plurality of hardware version data sets corresponding respectively to a plurality of reference count value ranges,
wherein said controller is configured to determine which one of the plurality of reference count value ranges covers the current count value, and obtain one of the plurality of hardware version data sets that corresponds to said one of the plurality of reference count value ranges thus determined from said memory circuit as the current hardware version data set.

6. The system as claimed in claim 1, wherein a difference between the reference voltage level and the second voltage level is less than a difference between the reference voltage level and the first voltage level.

7. The system as claimed in claim 1, wherein the first voltage level is 0 volts, the second voltage level is 3.3 volts, and the reference voltage level is 2.25 volts.

8. The system as claimed in claim 1, wherein the first voltage level is 3.3 volts, the second voltage level is 0 volts, and the reference voltage level is 0.8 volts.

9. A method for detecting hardware version, the method to be implemented by a detection circuit that includes an input/output (IO) pin adapted to be electrically connected to a timing circuit, said method comprising steps of:
A) operating in an output mode to pull a voltage at the IO pin to a first voltage level;
B) setting a current count value to a predetermined minimum count value;
C) operating in an input mode to allow the timing circuit to pull the voltage at the IO pin to a second voltage level that is different from the first voltage level in response to the detection circuit operating in the input mode, and to start counting to increase the current count value; and
D) obtaining a current hardware version data set based on the current count value.

10. The method as claimed in claim 9, wherein step D) includes sub-steps of:
D1) detecting the voltage at the IO pin and determining whether the voltage at the IO pin is between a reference voltage level and the second voltage level, where the reference voltage level is between the first voltage level and the second voltage level; and
D2) stopping counting to stop the increase of the current count value in response to the voltage at the IO pin being between a reference voltage level and the second voltage level, and obtaining the current hardware version data set based on the current count value.

11. The method as claimed in claim 9, wherein step D) includes sub-steps of:
D1) determining whether the current count value is abnormal;
D2) determining whether the voltage at the IO pin is between a reference voltage level and the second voltage level, where the reference voltage level is between the first voltage level and the second voltage level;
D3) stopping counting to stop the increase of the current count value; and
D4) obtaining the current hardware version data set based on the current count value,
wherein sub-step D2) is performed in response to determining in sub-step D1) that the current count value is not abnormal, and sub-step D4) is performed after sub-step D3) or in response to determining in sub-step D1) that the current count value is abnormal,
wherein sub-step D3) is performed in response to determining in sub-step D2) that the voltage at the IO pin is between a reference voltage level and the second voltage level, and
wherein sub-step D1 is repeated in response to determining in sub-step D2) that the voltage at the IO pin is not between the reference voltage level and the second voltage level.

12. The method as claimed in claim 11, wherein the current count value is abnormal when the current count value is equal to one of the predetermined minimum count value and a predetermined maximum count value that is greater than the predetermined minimum count value.

13. The method as claimed in claim 9, further comprising a step of, before step C):
Z) setting a recount value to a predetermined minimum recount value,
wherein step D) includes sub-steps of,
D1) detecting the voltage at the IO pin, and determining whether the voltage at the IO pin is between a reference voltage level and the second voltage level, where the reference voltage level is between the first voltage level and the second voltage level,
D2) stopping counting to stop the increase of the current count value,
D3) determining whether the current count value is abnormal,
D4) determining whether the recount value is greater than a predetermined maximum recount value, the predetermined maximum recount value being greater than the predetermined minimum recount value,
D5) increasing the recount value by one, waiting for a predetermined period of time, and after the predetermined period of time has passed, repeating sub-step D1), and
D6) obtaining the current hardware version data set based on the current count value,
wherein sub-step D2) is performed in response to determining in sub-step D1) that the voltage at the IO pin is between the reference voltage level and the second voltage level, and sub-step D1) is repeated in response to determining in sub-step D1) that the voltage at the IO pin is not between the reference voltage level and the second voltage level,
wherein sub-step D4) is performed in response to determining in sub-step D3) that the current count value is abnormal, and sub-step D6) is performed in response to determining in sub-step D3) that the current count value is not abnormal,
wherein sub-step D5) is performed in response to determining in sub-step D4) that the recount value is not greater than the predetermined maximum recount value, and sub-step D6 is performed in response to determining in sub-step D4) that the recount value is greater than the predetermined maximum recount value.

14. The method as claimed in claim 13, wherein the current count value is abnormal when the current count value is equal to the predetermined minimum count value.
